(19) United States
(12) Patent Application Publication
(10) Pub. No.: US 2026/0180424 A1
(43) Pub. Date: Jun. 25, 2026

(54) DRAIN SOURCE VOLTAGE MONITOR USING SOURCE STRAY INDUCTANCE

(71) Applicant: Renesas Electronics Corporation, Tokyo (JP)

(72) Inventors: Keita IKAI, Tokyo (JP); Daisuke KOBAYASHI, Tokyo (JP)

(73) Assignee: Renesas Electronics Corporation, Tokyo (JP)

(21) Appl. No.: 18/988,712

(22) Filed: Dec. 19, 2024

(51) Int. Cl. H02M 1/08; G01R 19/25; H02M 3/157; H02M 3/158

(52) U.S. Cl. CPC H02M 1/08; G01R 19/2506; H02M 3/157; H02M 3/158

(57) ABSTRACT

Semiconductor devices, systems and methods are described. A system can include a controller configured to generate a control signal, a power module and a gate driver. The gate driver can be configured to drive the power device according to the control signal. The gate driver can be further configured to measure a voltage across a source wire of the power device. The gate driver can be further configured to output the voltage across the source wire to the controller. The controller can be further configured to determine, based on at least the voltage across the source wire, an overshoot voltage associated with the power device. The controller can be further configured to determine, based on at least the overshoot voltage, a peak drain-source voltage of the power device. The controller can be further configured to adjust the control signal based on the determined peak drain-source voltage.

### BACKGROUND

The present disclosure relates in general to semiconductor devices. More specifically, the present disclosure relates to using source stray inductance to monitor peak drain source voltage of power devices.

Gate drivers are used in switching converter applications such as DC/DC converters, inverters, motor drivers, etc. These system can include a controller, one or more power devices (e.g., switch elements) and gate drivers for each switches. The gate drivers drive their respective power devices to on and off states according to the controller's signal and the system provides required output voltage or power to the load.

### SUMMARY

In one embodiment, a semiconductor device is generally described. The semiconductor device can include a driver and a circuit. The driver can be configured to receive a control signal from a controller. The driver can be further configured to generate, based on the control signal, a gate current to drive a power device. The circuit can be connected to a source terminal of the power device. The circuit can be configured to measure a voltage across a source wire of the power device. The circuit can be further configured to output the voltage across the source wire to the controller. The driver can be further configured to receive an adjusted control signal from the controller, wherein the adjusted control signal is based at least on the source stray inductance of the power device. The driver can be further configured to generate, based on the adjusted control signal, a new gate current to drive the power device.

In one embodiment, a system in a switching converter is generally described. The system can include a controller configured to generate a control signal, a half-bridge circuit, and a gate driver. The gate driver can be configured to drive a power device of the half-bridge circuit according to the control signal. The gate driver can be further configured to measure voltage across a source wire of the first power device. The gate driver can be further configured to output the voltage across the source wire to the controller. The controller can be further configured to determine, based on at least the voltage across the source wire, an overshoot voltage associated with the power device. The controller can be further configured to determine, based on at least the overshoot voltage, a peak drain-source voltage of the power device. The controller can be further configured to adjust the control signal based on the determined peak drain-source voltage.

In one embodiment, a method for operating a switching converter is generally described. The method can include measuring a voltage across a source wire of a power device. The method can further include determining, based on at least the voltage across the source wire, an overshoot voltage associated with the power device. The method can further include determining, based on at least the overshoot voltage, a peak drain-source voltage of the power device. The method can further include adjusting, based on the determined peak drain-source voltage, a control signal for driving the power device.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1A is a diagram showing a system that can implement drain source voltage monitor using source stray inductance in one embodiment.

FIG. 1B is a diagram showing another system that can implement drain source voltage monitor using source stray inductance in one embodiment.

FIG. 1C is a diagram showing another system that can implement drain source voltage monitor using source stray inductance in one embodiment.

FIG. 2A is a diagram showing an example implementation of drain source voltage monitor using source stray inductance in one embodiment.

FIG. 2B is a diagram showing another example implementation of drain source voltage monitor using source stray inductance in one embodiment.

FIG. 2C is a diagram showing another example implementation of drain source voltage monitor using source stray inductance in one embodiment.

FIG. 3A is a diagram showing a transition of a power module from an ON state to an OFF state during implementation of drain source voltage monitor using source stray inductance in one embodiment.

FIG. 3B is a diagram showing waveforms of signals during the transition shown in FIG. 3A.

FIG. 4A is a diagram showing a transition of a power module from an OFF state to an ON state during implementation of drain source voltage monitor using source stray inductance in one embodiment.

FIG. 4B is a diagram showing waveforms of signals during the transition shown in FIG. 4A.

FIG. 5 is a diagram showing another example implementation of drain source voltage monitor using source stray inductance in one embodiment.

FIG. 6 is a diagram showing another example implementation of drain source voltage monitor using source stray inductance in one embodiment.

FIG. 7 illustrates a flow diagram of a process to implement drain source voltage monitor using source stray inductance in one embodiment.

### DETAILED DESCRIPTION

In the following description, numerous specific details are set forth, such as particular structures, components, materials, dimensions, processing steps and techniques, to provide an understanding of the various embodiments of the present application. However, it will be appreciated by one of ordinary skill in the art that the various embodiments of the present application may be practiced without these specific details. In other instances, well-known structures or processing steps have not been described in detail to avoid obscuring the present application.

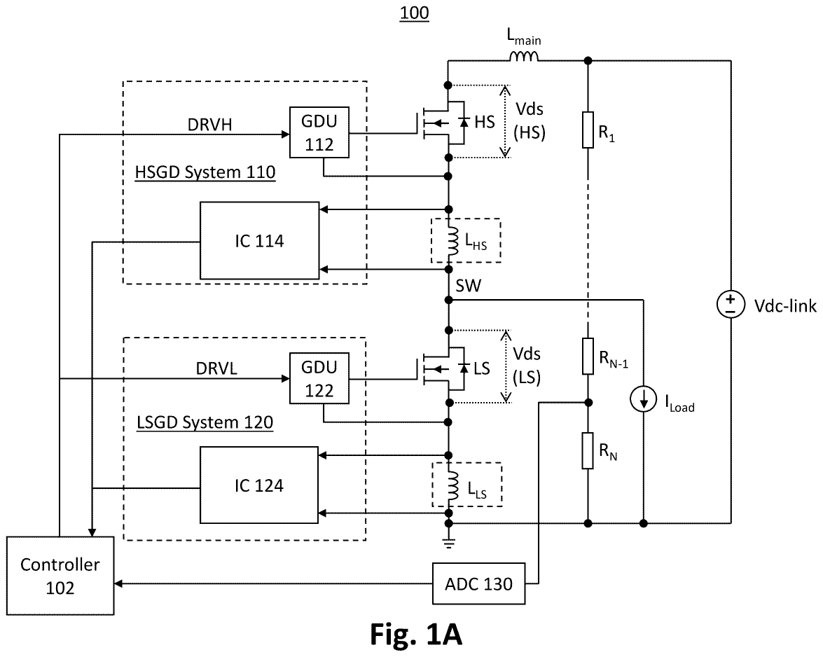

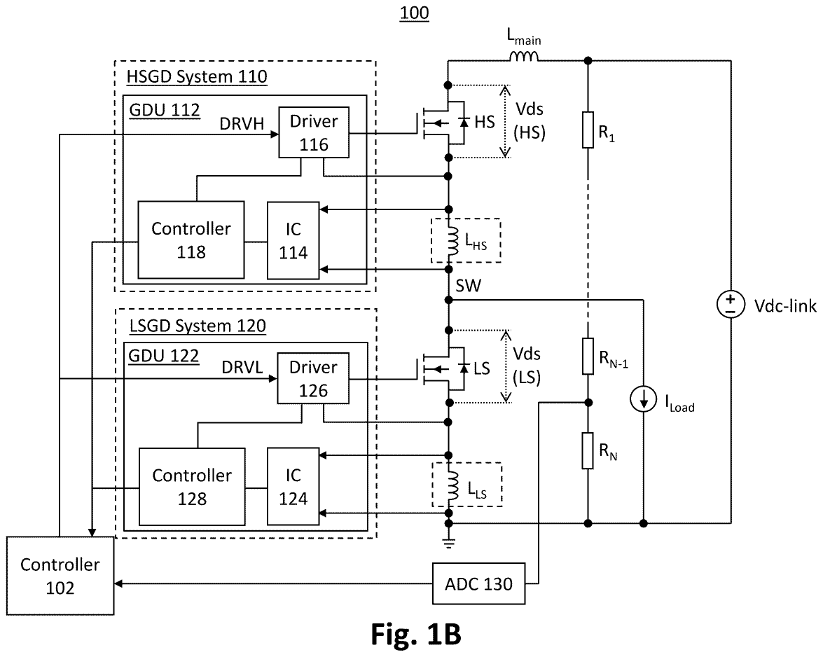

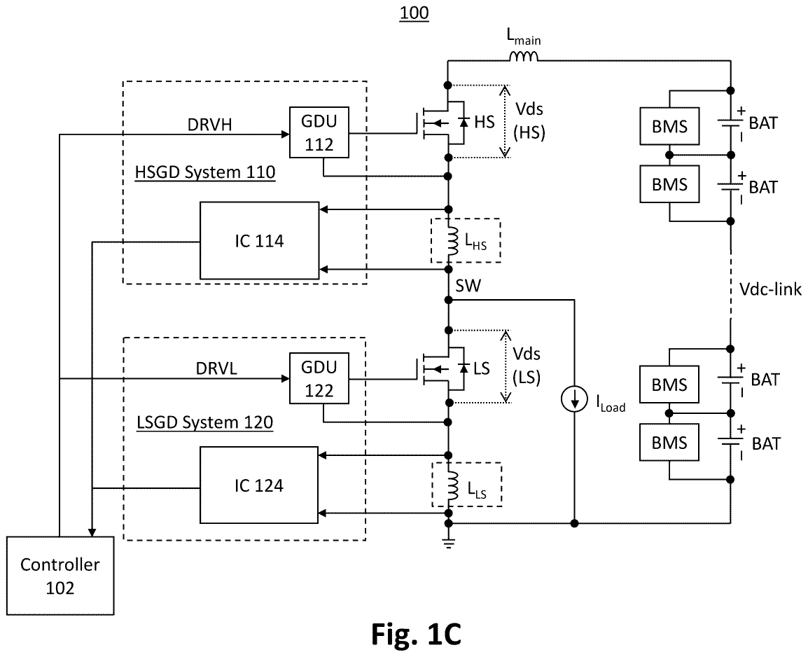

FIG. 1A is a diagram showing a system that can implement drain source voltage monitor using source stray inductance in one embodiment. An example system 100 shown in FIG. 1A can include at least a controller 102, a high-side gate driver (HSGD) system 110, a low-side gate driver (LSGD) system 120, a high-side power device HS, a low-side power device LS. The power devices HS and LS can form a power module that is implemented as a half-bridge circuit. Components of system 100 can be formed by one or more semiconductor devices. System 100 can be used in various applications, including but not limited to, solenoid drivers, buck converters, boost converters, traction inverters, battery chargers (e.g., on-board chargers in electric vehicles), or various other applications that utilized a power converter. Power devices HS and LS can be implemented by various devices, such as field-effect transistors (FETs) (e.g., metal oxide semiconductor field effect transistors (MOSFETs)) or various technologies (e.g., Silicon Carbide (SiC) devices), insulated-gate bipolar transistors (IGBTs), or other types of switching elements. In an aspect, each one of power devices HS and LS can include one or more switches (e.g., MOSFETs or IGBTs).

HSGD system 120 can include at least a gate drive unit (GDU) 112 and an integrated circuit (IC) 114. GDU 112 can be configured to generate different gate currents for driving a gate of power device HS. The gate currents being provided by GDU 112 can drive power device HS to an ON state or an OFF state. LSGD system 120 can include at least a gate drive unit (GDU) 122 and an IC 124. GDU 122 can be configured to generate different gate currents for driving a gate of power device LS. The gate currents being provided by GDU 122 can drive power device LS to an ON state and an OFF state. Each one of IC 114 and IC 124 can include a plurality of components, such as individual ICs and various active and passive electronic components, mounted on the same printed circuit board (PCB). A load can be connected to a switch node SW between power devices HS and LS, and as the power devices HS and LS are being switched alternately by GDU 112 and GDU 122, the load can draw a load current I_{load} from switch node SW.

A power supply can be connected across the drain of power device HS and the source of power device LS to provide supply voltage Vdc-link, which is a direct current (DC) voltage, to system 100. Controller 102 can control HSGD system 100 and LSGD system 120 to switch power devices HS and LS to supply load current I_{load} to the load drawing I_{load}. In one embodiment, if system 100 is being implemented for a traction inverter in a vehicle, then Vdc-link can be a battery voltage of a battery of the vehicle. In one embodiment, Vdc-link can be predefined by a user of system 100.

In another embodiment shown in FIG. 1B, IC 114 can be integrated in GDU 110 along with a gate driver 116 and a controller 118. Similarly, IC 124 can be integrated in GDU 120 along with a gate driver 126 and a controller 128. Gate drivers 116, 126 can include circuitry configured to generate the gate currents for driving power devices HS and LS, respectively. Controller, 102, 118, 128 can be microcontrollers or on-chip logic circuits. Controller 102 can be configured to generate control signals and provide the generated control signals (labeled as DRVH, DRVL in FIG. 1A) to GDU 112 and GDU 122. In one or more embodiments, control signals DRVH, DRVL can be derived from pulse width modulation (PWM) signals, pulse density modulation (PDM) signals, space vector modulation (SVM) signals, or other types of control signals that can control GDU 112 and GDU 122. In one or more embodiments, the control signals DRVH, DRVL can include gate drivability control signals provided by controller 102 to GDUs 112, 122 in addition to ON/OFF control signals such as PWM, PDM, SVM, or the like. Controllers 118, 128 can be configured to receive feedback signals (e.g., in the form of current and/or voltage) and use the feedback signals to control drivers 116, 126, respectively. In one or more embodiments, controllers 102, 118, 128 can be implemented in software, hardware, or some combination thereof. Controllers 102, 118, 128 can include one or more semiconductor devices (e.g., microcontroller, processor, control unit), and may be part of another controller (e.g., central processing unit (CPU), main controller, etc.).

In an aspect, power devices, such as power devices HS and LS, can suffer from high drain-source voltage (Vds) peak voltage during switching (e.g., from ON to OFF, or from OFF to ON). When the Vds peak voltage exceeds a safe operating area defined by a predefined range of voltages, the power device may be damaged. To avoid such damages, Vds peak voltage needs to be monitored and the gate drivability of the power device needs to be adjusted. Since Vds can reach relatively high voltage, monitoring Vds may require external components as well as components that occupy printed circuit board (PCB) area for creepage, thus increasing cost and complexity.

Some conventional techniques include monitoring Vds using a resistor divider. However, the resistor divider can require a significant number of components and to monitor high-voltage power devices, the resistor divider design may need to be specially designed to handle creepage/clearance and quality/reliability. Further, signals can be delayed and suppressed due to the parasitic capacitances in the resistor divider, and Vds of both high-side and low-side devices need to be monitored. Other conventional techniques include detecting high Vds using a Zener diode, such as detecting when Vds exceeds the Zener diode's breakdown voltage. However, the Zener diode can provide the information whether Vds is high or low, but does not quantify the Vds peak voltage. Further, the detection of Vds can vary with temperature due to the Zener diode's breakdown voltage varying with temperature. A rate of change of Vds can also be impacted by the junction capacitance of the Zener diode. Also, Vds of both high-side and low-side devices need to be monitored.

To be described herein, a Vds peak voltage can be estimated based on the DC-link supply voltage Vdc-link and an overshoot voltage in the main power loop, where the main power loop is the loop including Vdc-link and the power module formed by power devices HS and LS. Hence, in the descriptions herein, the Vds overshoot voltage can be an overshoot voltage applied to either one of the drain-source voltages of power devices HS and LS. In the embodiment shown in FIG. 1A, a plurality of resistors R₁, . . . , R_{N} can be connected in series between the drain of power device HS, and the source of power device LS. An analog-to-digital converter (ADC) 130 can be connected to a node X among the plurality of resistors, such as between R_{N-1} and R_{N} shown in FIG. 1A, to measure Vdc-link. ADC 130 can output Vdc-link as a digital signal encoding a voltage level of Vdc-link. In another embodiment shown in FIG. 1C, the voltage Vdc-link can be generated by a stack of batteries (“BAT”), where each battery can be managed by a battery management system (BMS). The stack of BMS can control voltages across individual batteries in the stack to generate a desired value of Vdc-link, and the generation of the desired value of Vdc-link can be an alternative to using ADC 130 to measure Vdc-link. In an aspect, the total stray inductance of wires in the main power loop can be equivalent to a sum of stray inductances L_{HS}, L_{LS} and Lₘₐᵢₙ. The source stray inductance L_{HS} can be a stray inductance of a wire connected to the source (e.g., source wire) of power device HS. The source stray inductance L_{LS} can be a stray inductance of a wire connected to the source (e.g., source wire) of power device LS. The stray inductance Lₘₐᵢₙ can be a stray inductance of wires in the main power loop other than the source wires having stray inductances L_{HS}, L_{LS}. In the present disclosure, the stray inductance of a wire connected to a source of a power device can be referred to as a source stray inductance, and the voltage across a source wire can be referred to a voltage across a source stray inductance. Further, in the present disclosure, the source wire having stray inductance L_{LS} can be referred to as source wire L_{LS}, the source wire having stray inductance L_{HS} can be referred to as source wire L_{HS}, and the wires having stray inductance Lₘₐᵢₙ can be referred to as wires Lₘₐᵢₙ.

The Vds overshoot voltage can be monitored by IC 114 and/or IC 124 described herein. IC 114 and IC 124 can measure or monitor the voltages across the source wire (e.g., both ends of the source wire connected to a source of a power device) in the main power loop, such as source wires L_{HS} for power device HS and L_{LS} for power device LS. In an aspect, the source stray inductance of a source wire of a power device can induce a voltage when the drain-source current Ids of the power device changes. This induced voltage can be measured by IC 114 and/or IC 124 and the measurement can be Vds overshoot voltage that reflects the source stray inductance. Since the voltages being measured from source wires are used, no additional components for sensing are needed, thus requiring lower cost. Further, the measured voltages across the source wire can be relatively small, such that special design for high voltage monitoring may not be needed. Furthermore, the Vds overshoot voltage can be monitored from one of power devices HS and LS. ICs 114, 124 can process the voltages across the source wires and provide the voltages to controller 102. Controller 102 can estimate the Vds overshoot voltage using Vdc-link and the voltages across the source wires, and controller 102 can optimize gate drivability of the power device based on the estimated Vds overshoot voltage.

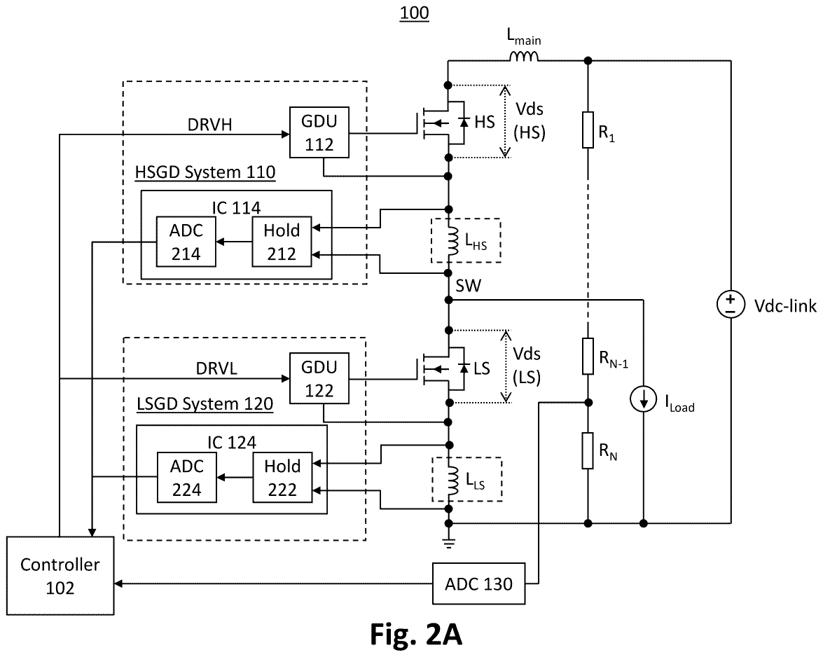

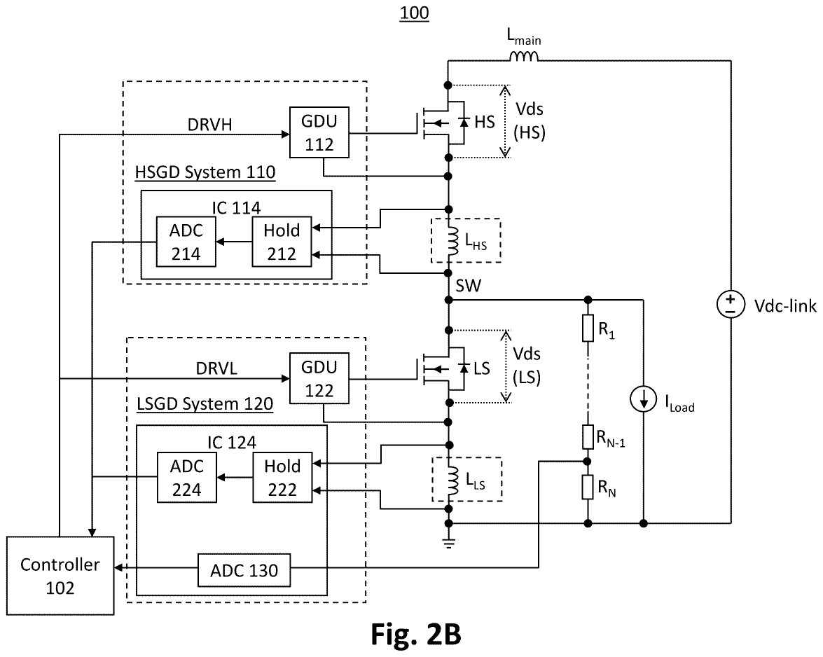

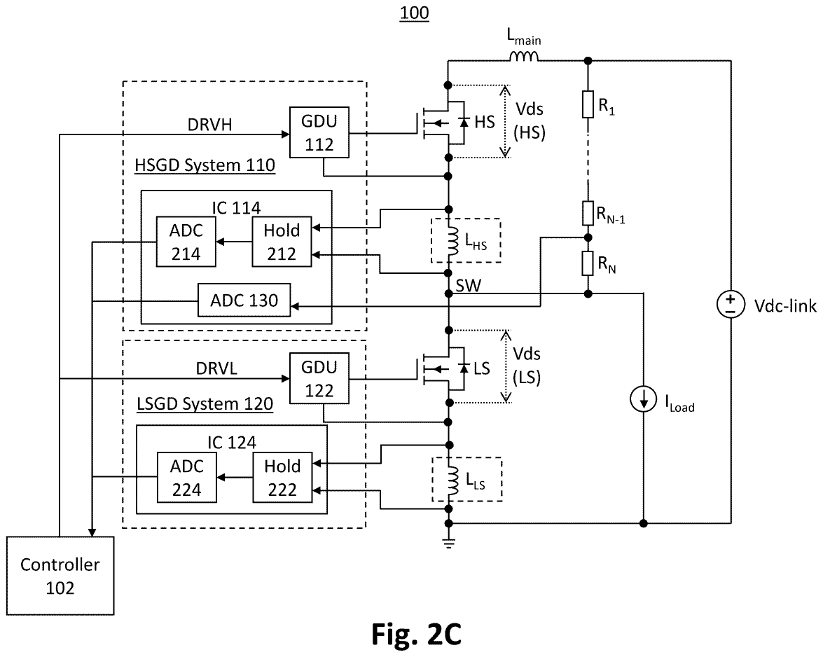

FIG. 2A is a diagram showing an example implementation of drain source voltage monitor using source stray inductance in one embodiment. Descriptions of FIG. 2A can reference components shown in FIG. 1A. In the example implementation shown in FIG. 2A, IC 114 can include a hold circuit 212 and an ADC 214, and IC 124 can include a hold circuit 222 and an ADC 224. In one embodiment, controller 102 can activate one of IC 114 and IC 124 to obtain or measure a peak voltage across a source wire for estimating Vds overshoot voltage. In one embodiment, IC 114 can be integrated in GDU 112 and IC 124 can be integrated in GDU 122. In another embodiment, IC 114 and its components can be discrete components mounted on the same PCB as GDU 112 and IC 124 and its components can be discrete components mounted on the same PCB as GDU 122. In one embodiment, one of IC 114 and IC 124 can be included in system 100. In other embodiments, ADC 130 can be integrated in either one of IC 114 (FIG. 2C) or IC 124 (FIG. 2B), such that IC 114 and IC 124 can measure Vdc-link.

Hold circuit 212 can be a peak hold circuit configured to hold a peak value of the detected voltage across L_{HS}. Hold circuit 212 can provide the peak voltage across the source wire L_{HS} to ADC 214 and ADC 214 can convert the peak voltage across the source wire Las into a digital signal encoding the peak voltage across the source wire L_{HS}. ADC 214 can send the digital signal encoding the peak voltage across the source wire L_{HS} to controller 102. When IC 114 is activated, the peak voltage across the source wire L_{HS} can be used by controller 102 to estimate the Vds overshoot voltage.

Hold circuit 222 can be a peak hold circuit configured to hold a peak voltage across source wire L_{LS}. Hold circuit 222 can provide the peak voltage across source wire L_{LS} to ADC 224 and ADC 224 can convert the peak voltage across source wire L_{LS} into a digital signal encoding the peak voltage across source wire L_{LS}. ADC 224 can send the digital signal encoding the peak voltage across source wire L_{LS} to controller 102. When IC 124 is activated, the peak voltage across source wire L_{LS} can be used by controller 102 to estimate the Vds overshoot voltage.

Controller 102 can include storage devices such as memory devices and registers. In one embodiment, controller 102 can write a value of Vdc-link to a register and the voltage across source wires provided by one or more of IC 114 and IC 124 to another register. Controller 102 can read these registers to obtain the values in an estimation of the Vds overshoot voltage. In one embodiment, the Vds overshoot voltage V_{OVERSHOOT} can be dependent on the stray inductance Lₘₐᵢₙ and the source stray inductances of power devices HS and LS in the main power loop, such as:

$${V}_{O V E R S H O O T} = ( {L}_{m a i n} + {L}_{H S} + {L}_{L S} ) \frac{{dI}_{D S}}{dt} where \frac{{dI}_{D S}}{dt}$$

is the rate of change of the drain-source current I_{DS} of the corresponding power module with respect to time. For example, if IC 114 is activated and IC 124 is deactivated, then

$$\frac{{dI}_{D S}}{dt}$$

is the rate of change of I_{DS} of power device HS. If IC 124 is activated and IC 114 is deactivated, then

$$\frac{{dI}_{D S}}{dt}$$

is the rate of change of I_{DS} of power device LS. In one embodiment, controller 102 can sense IDS using various current sensing techniques, such as using current sensing resistors connected between the source of the power modules and controller 102.

Upon determining or estimating overshoot voltage V_{OVERSHOOT}, controller 102 can determine or estimate the Vds peak voltage based on a relationship among V_{OVERSHOOT}, Vds of power devices HS and LS, and Vdc-link, such as:

$$Vds = {V}_{DC - Link} - Vds ( otherside ) + {V}_{O V E R S H O O T} \qquad ( 1 )$$

where V_{DC-Link} is Vdc-link, and Vds(otherside) is the Vds of the otherside power device. When Vds is the drain-source voltage of power device HS and Vds(otherside) is the drain-source voltage of power device LS, such as Vds(HS)=V_{DC-Link}−Vds(LS)+V_{OVERSHOOT}. When Vds is the drain-source voltage of power device LS and Vds(otherside) is the drain-source voltage of power device HS, such as Vds(LS)=V_{DC-Link}−Vds(HS)+V_{OVERSHOOT}.

Based on the relationship among V_{OVERSHOOT}, Vds of power devices HS and LS, and Vdc-link, controller 102 can determine or estimate the peak Vds voltage. When IC 114 is activated, controller 102 can determine or estimate a peak of V_{OVERSHOOT} based on the following relationship:

$$Max ( {V}_{O V E R S H O O T} ) \leq \frac{{L}_{m a i n} + {L}_{H S} + {L}_{L S}}{{L}_{HS}} \times Max ( {V}_{H S} ) \qquad ( 2 )$$

where Max(V_{OVERSHOOT}) is the peak value of V_{OVERSHOOT} and Max(V_{HS}) is the peak voltage of the voltage across the source wire having stray inductance L_{HS}.

When IC 124 is activated, controller 102 can determine or estimate the peak of V_{OVERSHOOT} based on the following relationship:

$$Max ( {V}_{O V E R S H O O T} ) \leq \frac{{L}_{m a i n} + {L}_{H S} + {L}_{L S}}{{L}_{L S}} \times Max ( {V}_{L S} ) \qquad ( 3 )$$

where Max(V_{OVERSHOOT}) is the peak value of V_{OVERSHOOT} and Max(V_{LS}) is the peak voltage of the source stray inductance L_{LS}. Note that the source stray inductance values tend to be relatively small, hence the voltages of the source stray inductances can be relatively small as well and can be handled by low voltage circuits. To be described in more detail below, controller 102 can further determine the Vds peak voltage under different transitions (e.g., from ON to OFF and from OFF to ON) using the relationships above.

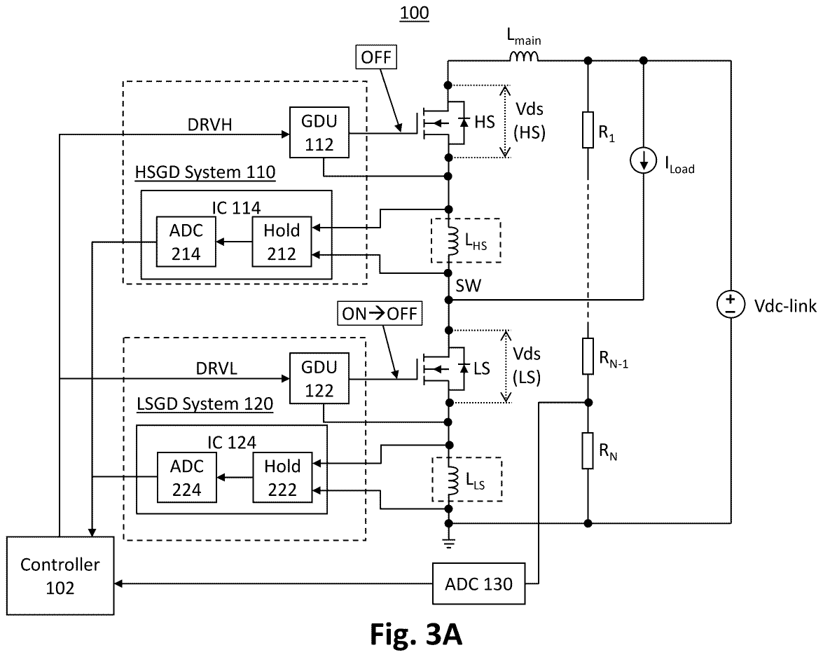

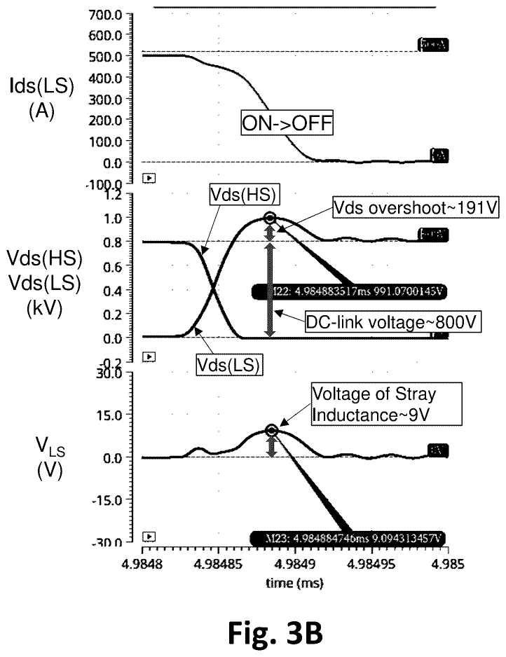

FIG. 3A is a diagram showing a transition of a power device from an ON state to an OFF state during implementation of drain source voltage monitor using source stray inductance in one embodiment. FIG. 3B is a diagram showing waveforms of signals during the transition shown in FIG. 3A. Descriptions of FIG. 3A and FIG. 3B can reference components shown in FIG. 1A and FIG. 2A. In an example shown in FIG. 3A, power device HS is OFF, power device LS is transitioning from ON to OFF, IC 124 is activated and IC 114 is deactivated. Since IC 124 is activated and IC 114 is deactivated, Vds is the Vds of power device LS and Vds(otherside) is the Vds of power device HS. When power device LS transitions from ON to OFF, the Vds of the other side, or Vds of power device HS, can be relatively small and negligible. Therefore, when power device LS transitions from ON to OFF, controller 102 can determine the Vds peak voltage using relationship (1) and (3) above, such as:

$$V ds ( peak ) \approx {V}_{D C - L i n k -} + \frac{{L}_{m a i n} + {L}_{H S} + {L}_{L S}}{{L}_{L S}} \times Max ( {V}_{L S} ) \qquad ( 4 )$$

where Vds(peak) is the Vds peak voltage. Note that Vds(otherside) is not included in relationship (4) since it can be set to zero when it is negligible.

Referring to FIG. 3B, when power device LS transitions from ON to OFF, the drain-source current Ids of power device LS can drop to zero. In an aspect, when power device HS is OFF and power device LS is ON, hard switching can occur to first transition power device LS from ON to OFF. When both power devices HS and LS are OFF, then the body diode of the power device HS or freewheeling diode conducts current to complete the hard switching as shown in FIG. 3A and FIG. 3B (e.g., the diode shown in parallel with power device HS will conduct current from its anode to cathode). As Ids of power device LS begins to drop to transition power device LS from ON to OFF, Vds(LS) can begin to increase and Vds(HS) can begin to decrease (but HS is not turned ON, the body diode or freewheeling diode of HS will be turned ON). In FIG. 3B, power device LS reach its OFF state and Vds(LS) can reach Vdc-link, which is approximately 800V, but an overshoot can occur and pushes Vds(LS) up by another 191V. If the sum of these voltages, 800V+191V=991V, exceeds the allowable operating voltage range of power device LS, then power device LS may be damaged. At the time of the voltage overshoot, the voltage V_{LS} of the source stray inductance L_{LS} also reaches its peak. Therefore, controller 102 can determine the peak Vds(LS) using the peak of the voltage of the source stray inductance L_{LS}, the overshoot voltage and the DC link voltage Vdc-link received from ADC 130. The example embodiments shown in FIG. 3A and FIG. 3B are also applicable to situations where power device LS is OFF, power device HS is transitioning from ON to OFF, IC 114 is activated and IC 124 is deactivated.

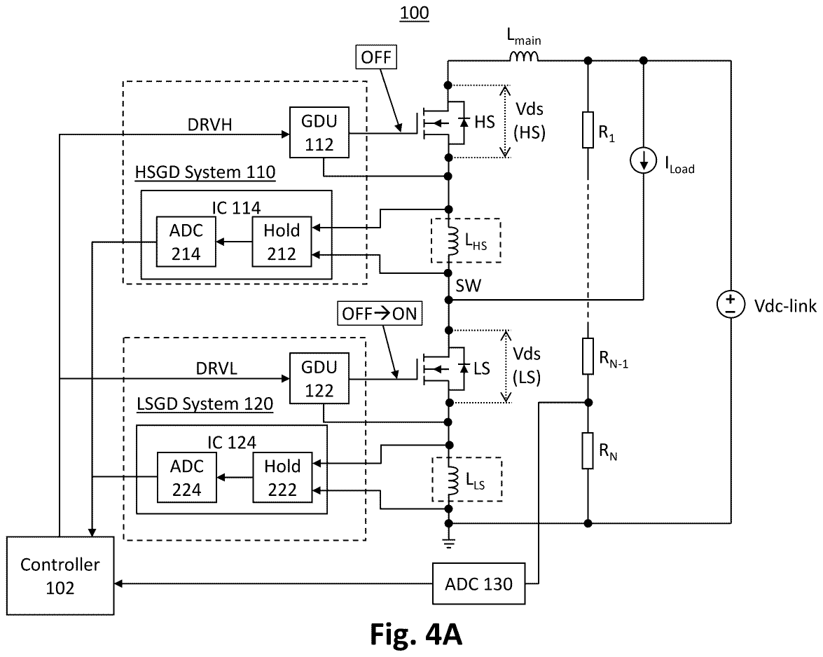

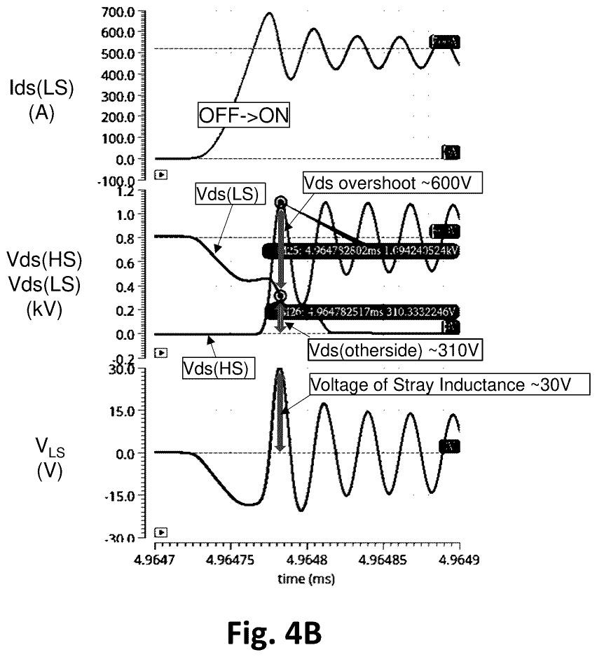

FIG. 4A is a diagram showing a transition of a power device from an OFF state to an ON state during implementation of drain source voltage monitor using source stray inductance in one embodiment. FIG. 4B is a diagram showing waveforms of signals during the transition shown in FIG. 4A. Descriptions of FIG. 4A and FIG. 4B can reference components shown in FIG. 1A to FIG. 2A. In an example shown in FIG. 4A, the body diode or freewheeling diode of power device HS is ON, power device LS is transitioning from OFF to ON, IC 124 is activated and IC 114 is deactivated. Since IC 124 is activated and IC 114 is deactivated, Vds is the Vds of power device HS and Vds(otherside) is the Vds of power device LS. When power device LS transitions from OFF to ON, the Vds of the other side, or Vds of power device LS, can be relatively large and cannot be negligible. Therefore, when power device LS transitions from OFF to ON, controller 102 can determine the Vds peak voltage using relationship (1) and (3) above, such as:

$$Vds ( peak ) \leq {V}_{D C - L i n k} + \frac{{L}_{m a i n} + {L}_{H S} + {L}_{L S}}{{L}_{L S}} \times Max ( {V}_{L S} ) - Vds ( otherside ) \qquad ( 5 )$$

where Vds(peak) is the Vds peak voltage. Note that comparing to relationship (4) above, Vds(otherside) is included in relationship (5) since it is not negligible.

Referring to FIG. 4B, when power device LS transitions from OFF to ON, the drain-source current Ids of power device LS can increase. In an aspect, when body diode of power device HS or freewheeling diode is ON and power device LS is OFF, hard switching can occur to first transition power device LS from OFF to ON. When power device LS flows all the load current I_{LOAD}, the body diode of power device HS or freewheeling diode becomes OFF and completes the hard switching as shown in FIG. 4A and FIG. 4B. As Ids of power device LS begins to increase to transition power device LS from OFF to ON, Vds(LS) can begin to decrease and Vds(HS) can begin to increase. In FIG. 4B, the body diode of power device HS or freewheeling diode reaches its OFF state and Vds(HS) can reach Vdc-link, which is approximately 800V, but an overshoot can occur and pushes Vds(HS) or Vds(otherside) up to a level greater than 800V. If the sum of these voltages, 800V+600V−310V=1,090V, exceeds the allowable operating voltage range of power device HS, then power device HS may be damaged. Further, when the overshoot occurs, Vds(LS) is still fluctuating and not yet stabilized, and also not fully turned on, thus a non-zero Vds(LS) can be measured. Therefore, controller 102 can determine the peak Vds(HS) by subtracting Vds(otherside) from a sum of the DC link voltage and Vds (overshoot) at the time when the overshoot voltage occurs. The example embodiments shown in FIG. 4A and FIG. 4B are also applicable to situations where power device LS is OFF, power device HS is transitioning from OFF to ON, IC 114 is activated and IC 124 is deactivated.

The Vds peak voltages determined or estimated by controller 102 with respect to the embodiments shown in FIG. 3A to FIG. 4B can be considered as worst Vds peak voltages. Based on the Vds peak voltages determined or estimated, controller 102 can make adjustments to the control signals DRVH and DRVL for HSGD system 110 and LSGD system 120 to drive power devices HS and LS in optimal manner. For example, controller 102 can adjust control signals DRVH and DRVL to modify one or more of switching speed, switching frequencies, ON times, or other switching parameters of power devices HS and LS that can reduce the Vds peak voltage to prevent damages to power devices HS and LS. For example, if the estimated Vds peak voltage is at an unsafe level that can damage a power device, controller 102 can adjust the control signals to reduce the amplitude of the gate current during OFF to ON transition (e.g., FIG. 4A, 4B) to reduce voltage overshoot that contributes to the Vds peak voltage.

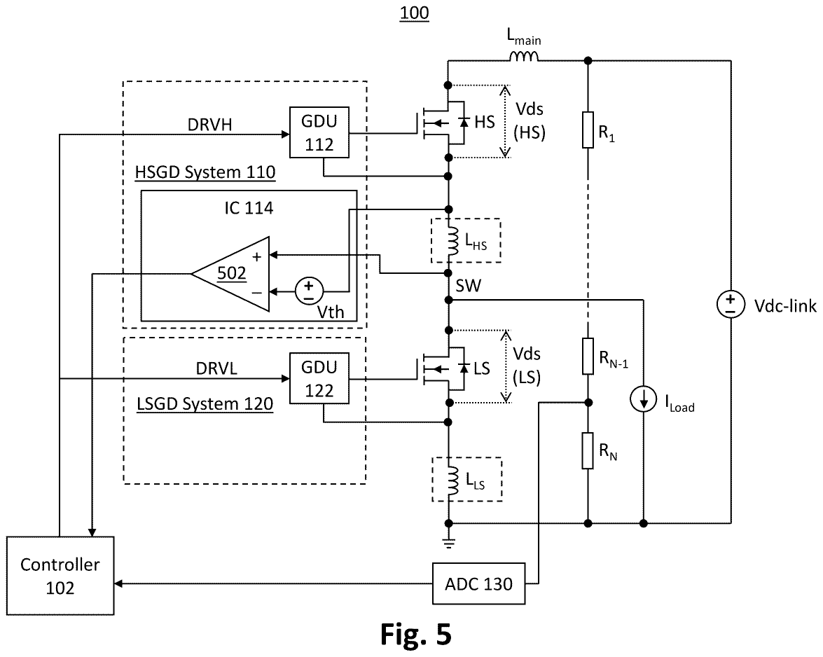

FIG. 5 is a diagram showing another example implementation of drain source voltage monitor using source stray inductance in one embodiment. Descriptions of FIG. 5 can reference components shown in FIG. 1A to FIG. 4B. In the example implementation shown in FIG. 5, HSGD system 100 can include IC 114, and IC 114 can include a comparator 502. In the embodiment shown in FIG. 5, HSGD system 100 can include IC 114 and LSGD system 120 may not include IC 124. In another embodiment, both IC 114 and IC 124 can include comparator 502. Comparator 502 can be used for determining whether the voltage across source wire of the corresponding power device exceeds a predefined voltage threshold Vth, and output a high voltage to controller 102 if the voltage across the source wire exceeds Vth. The comparison being performed by comparator 502 monitor whether an overshoot has occurred in the main power loop.

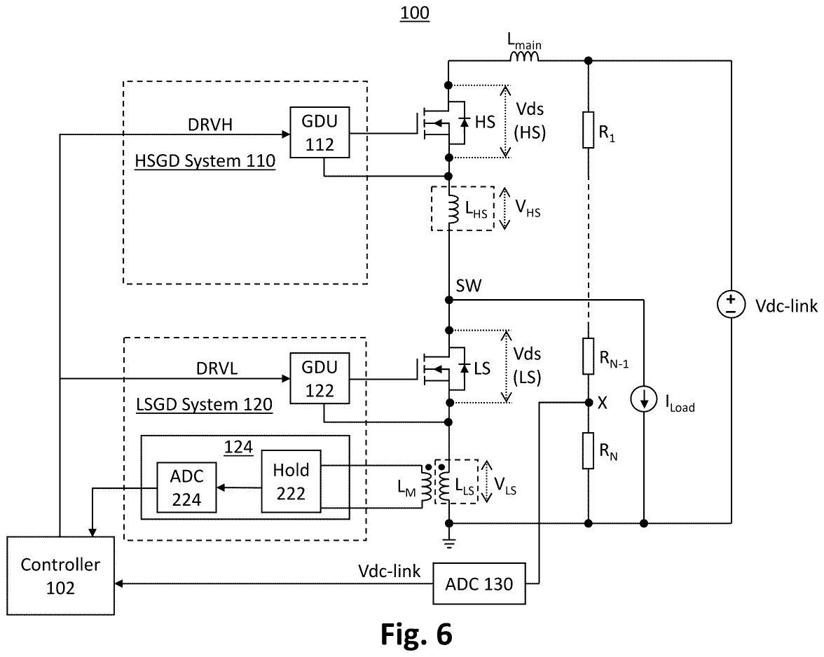

FIG. 6 is a diagram showing another example implementation of drain source voltage monitor using source stray inductance in one embodiment. Descriptions of FIG. 6 can reference components shown in FIG. 1A to FIG. 5. In the example implementation shown in FIG. 6, LSGD system 100 can include IC 124, and IC 124 can include hold circuit 222 and ADC 224. In the embodiment shown in FIG. 6, LSGD system 100 can include IC 124 and HSGD system 110 may not include IC 114. In the embodiment shown in FIG. 6, an input of hold circuit 222 can be connected to a sensing wire having an inductance L_{M}. In one embodiment, when both IC 114 and IC 124 includes their respective hold circuit and ADC (see FIG. 2A), the sensing wire having inductance L_{M} can be connected to each one of the hold circuits. The sensing wire having inductance L_{M} can be used for monitoring the voltage across the source wire of the corresponding power module by mutual inductance.

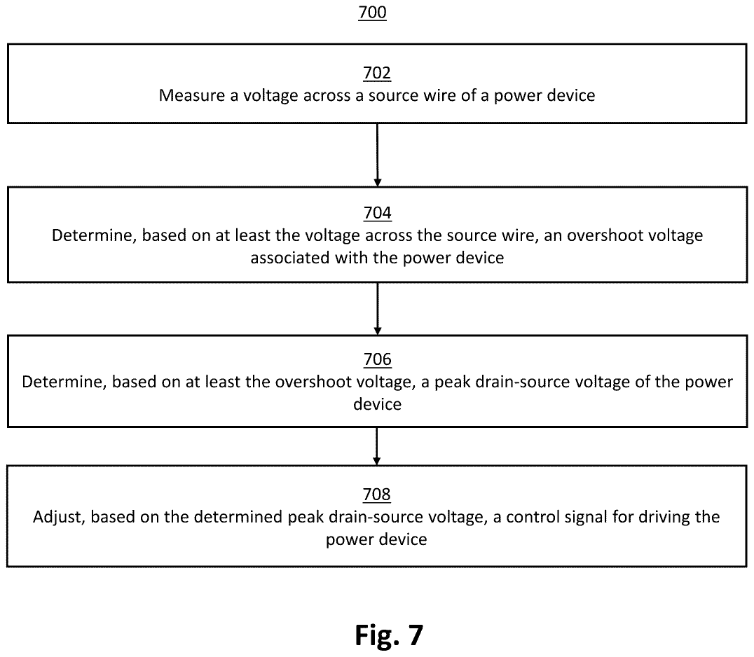

FIG. 7 illustrates a flow diagram of a process to implement drain source voltage monitor using source stray inductance in one embodiment. The process 700 shown in FIG. 7 can include one or more operations, actions, or functions as illustrated by one or more of blocks 702, 704, 706 and/or 708. Although illustrated as discrete blocks, various blocks can be divided into additional blocks, combined into fewer blocks, eliminated, performed in different order, or performed in parallel, depending on the desired implementation.

Process 700 can be performed by a power conversion system, such as system 100, described herein. Process 700 can begin at block 702. At block 702, a gate driver of the power conversion system can measure a voltage across a source wire of a power device. In one embodiment, the power device can be one of a high-side power device and a low-side power device in a power converter. In one embodiment, the gate driver can measure the voltage across the source wire by operating a peak hold circuit to detect the voltage across the source wire is greater than a predefined threshold and to hold a peak value of the voltage across the source wire. In one embodiment, the gate driver can measure the voltage across the source wire by measuring a mutual inductance between an inductor and the source wire.

Process 700 can proceed from block 702 to block 704. At block 704, a controller of the power conversion system can determine, based on at least the voltage across the source wire, an overshoot voltage associated with the power module. Process 700 can proceed from block 704 to block 706. At block 706, the controller can determine, based on at least the overshoot voltage, a peak drain-source voltage of the power module. Process 700 can proceed from block 706 to block 708. At block 708, the controller can adjust, based on the determined peak drain-source voltage, a control signal for driving the power device.

In one embodiment, the power device can be a first power device among a pair of power devices including a high-side power device and a low-side power device in a power module. The pair of power devices and at least one wire having stray inductances can form a main power loop. The at least one wire can include the source wire of the first power device and a source wire of a second power device among the pair of power devices. The gate driver can determine the overshoot voltage based on the stray inductances of the at least one wire in the main power loop and a maximum of the voltage across the source wire of the first power device. The gate driver can further determine the peak drain-source voltage of the power device based on the overshoot voltage, a drain-source voltage of the second power device, and a DC link voltage of the main power loop. In one embodiment, during a transition of the power device from an ON state to an OFF state, the gate driver can set the drain-source voltage of a second power device among the pair of power devices to zero, and determine the peak drain-source voltage of the power device based on the overshoot voltage and the DC link voltage of the main power loop.

### EXAMPLES

Example 1: A semiconductor device comprising: a driver configured to: receive a control signal from a controller; generate, based on the control signal, a gate current to drive a power device; a circuit connected to a source terminal of the power device, the circuit being configured to: measure a voltage across a source wire of the power device; output the voltage across the source wire to the controller; the driver being further configured to: receive an adjusted control signal from the controller, wherein the adjusted control signal is based at least on the voltage across the source wire of the power device; and generate, based on the adjusted control signal, a new gate current to drive the power device.

Example 2: The semiconductor device of Example 1, wherein the power device is one of a high-side power device and a low-side power device in a power module.

Example 3: The semiconductor device of any one of Example 1 and Example 2, wherein the circuit comprises: a hold circuit configured to: hold a peak value of the voltage across the source wire; and an analog-to-digital converter (ADC) configured to convert the peak value of the voltage across the source wire into a digital signal, wherein output of the voltage across the source wire to the controller comprises outputting the digital signal to the controller.

Example 4: The semiconductor device of any one of Example 1 to Example 3, further comprising a sensing wire connected to the hold circuit, wherein the voltage across the source wire is based on mutual inductance between the sensing wire and the source wire.

Example 5: The semiconductor device of any one of Example 1 to Example 4, wherein the circuit comprises: a comparator configured to: determine the voltage across the source wire is greater than a predefined threshold; and in response to the determination that the voltage across the source wire is greater than the predefined threshold, output a signal to the controller that indicates the voltage across the source wire greater than the predefined threshold.

Example 6: A system comprising: a controller configured to generate a control signal; a half-bridge circuit; and a gate driver configured to: drive a first power device of the half-bridge circuit according to the control signal; measure a voltage across a source wire of the first power device in the half-bridge driver; output the voltage across the source wire to the controller; the controller is further configured to: determine, based on at least the voltage across the source wire, an overshoot voltage associated with the first power device; determine, based on at least the overshoot voltage, a peak drain-source voltage of the first power device; and adjust the control signal based on the determined peak drain-source voltage.

Example 7: The system of Example 6, wherein the half-bridge driver includes a high-side power device and a low-side power device in a power module, and the first power device is one of the high-side power device and the low-side power device.

Example 8: The system of any one of Example 6 and Example 7, wherein the gate driver comprises: a hold circuit configured to: hold a peak value of the voltage across the source wire; and an analog-to-digital converter (ADC) configured to convert the peak value of the voltage across the source wire into a digital signal, wherein output of the voltage across the source wire to the controller comprises outputting the digital signal to the controller.

Example 9: The system of any one of Example 6 to Example 8, further comprising a sensing wire connected to the hold circuit, wherein the voltage across the source wire is measured by the gate driver based on mutual inductance between the sensing wire and the source wire.

Example 10: The system of any one of Example 6 to Example 9, wherein the gate driver comprises: a comparator configured to: determine the voltage across the source wire is greater than a predefined threshold; and in response to the determination that the voltage across the source wire is greater than the predefined threshold, output a signal to the controller that indicates the voltage across the source wire is greater than the predefined threshold.

Example 11: The system of any one of Example 6 to Example 10, further comprising an ADC configured to: detect a direct current (DC) link voltage of a main power loop supplied to the half-bridge driver; and sending the DC link voltage to the controller, wherein the controller is configured to determine a peak drain-source voltage of the first power device based on at least the overshoot voltage and the DC link voltage.

Example 12: The system of any one of Example 6 to Example 11, wherein the half-bridge driver includes a high-side power device and a low-side power device in a power module, and the controller is configured to determine the overshoot voltage based on voltages across source wires of both the high-side power device and the low-side power device.

Example 13: The system of any one of Example 6 to Example 12, wherein: the half-bridge driver includes a main power loop formed by at least one wire having stray inductances and a pair of power devices including a high-side power device and a low-side power device in a power module; the first power device is one of the pair of power devices; the at least one wire includes the source wire of the first power device and a source wire of a second power device among the pair of power devices; the controller is configured to: determine the overshoot voltage based on the stray inductances of the at least one wire in the main power loop and a maximum of the voltage across the source wire of the first power device; and determine the peak drain-source voltage of the power device based on the overshoot voltage, a drain-source voltage of the second power device, and a DC link voltage of the main power loop.

Example 14: The system of any one of Example 6 to Example 13, wherein the controller is configured to, during a transition of the first power device from an ON state to an OFF state: set the drain-source voltage of the second power device to zero; and determine the peak drain-source voltage of the power device based on the overshoot voltage and the DC link voltage of the main power loop.

Example 15: A method comprising: measuring a voltage across a source wire of a power device; determining, based on at least the voltage across the source wire, an overshoot voltage associated with the power device; determining, based on at least the overshoot voltage, a peak drain-source voltage of the power device; and adjusting, based on the determined peak drain-source voltage, a control signal for driving the power device.

Example 16: The method of Example 15, wherein the power device is one of a high-side power device and a low-side power device in a power module.

Example 17: The method of any one of Example 15 and Example 16, wherein measuring the voltage across the source wire comprises operating a peak hold circuit to hold a peak value of the voltage across the source wire.

Example 18: The method of any one of Example 15 to Example 17, wherein measuring the voltage across the source wire comprises measuring a mutual inductance between a sensing wire and the source wire.

Example 19: The method of any one of Example 15 to Example 18, wherein: the power device is a first power device among a pair of power devices including a high-side power device and a low-side power device in a power module; the pair of power devices and at least one wire having stray inductances form a main power loop; the at least one wire includes the source wire of the first power device and a source wire of a second power device among the pair of power devices; the method further comprising: determining the overshoot voltage based on the stray inductances of the at least one wire in the main power loop and a maximum of the voltage across the source wire of the first power device; and determining the peak drain-source voltage of the power device based on the overshoot voltage, a drain-source voltage of the second power device, and a DC link voltage of the main power loop.

Example 20: The method of any one of Example 15 to Example 19, further comprising: during a transition of the power device from an ON state to an OFF state, setting the drain-source voltage of a second power device among the pair of power devices to zero; and determining the peak drain-source voltage of the power device based on the overshoot voltage and the DC link voltage of the main power loop.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The disclosed embodiments of the present invention have been presented for purposes of illustration and description but are not intended to be exhaustive or limited to the invention in the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A semiconductor device comprising:
a driver configured to:
receive a control signal from a controller; and
generate, based on the control signal, a gate current to drive a power device; and
a circuit connected to a source terminal of the power device, the circuit being configured to:
measure a voltage across a source wire of the power device; and
output the voltage across the source wire to the controller,
wherein the driver is further configured to:
receive an adjusted control signal from the controller, wherein the adjusted control signal is based at least on the voltage across the source wire of the power device; and
generate, based on the adjusted control signal, a new gate current to drive the power device.

2. The semiconductor device of claim 1, wherein the power device is one of a high-side power device and a low-side power device in a power module.

3. The semiconductor device of claim 1, wherein the circuit comprises:
a hold circuit configured to hold a peak value of the voltage across the source wire; and
an analog-to-digital converter (ADC) configured to convert the peak value of the voltage across the source wire into a digital signal, wherein output of the voltage across the source wire to the controller comprises outputting the digital signal to the controller.

4. The semiconductor device of claim 3, further comprising a sensing wire connected to the hold circuit, wherein the voltage across the source wire is based on mutual inductance between the sensing wire and the source wire.

5. The semiconductor device of claim 1, wherein the circuit comprises:
a comparator configured to:
determine the voltage across the source wire is greater than a predefined threshold; and
in response to the determination that the voltage across the source wire is greater than the predefined threshold, output a signal to the controller that indicates the voltage across the source wire greater than the predefined threshold.

6. A system comprising:
a controller configured to generate a control signal;
a half-bridge circuit; and
a gate driver configured to:
drive a first power device of the half-bridge circuit according to the control signal;
measure a voltage across a source wire of the first power device in the half-bridge circuit; and
output the voltage across the source wire to the controller;
wherein the controller is further configured to:
determine, based on at least the voltage across the source wire, an overshoot voltage associated with the first power device;
determine, based on at least the overshoot voltage, a peak drain-source voltage of the first power device; and
adjust the control signal based on the determined peak drain-source voltage.

7. The system of claim 6, wherein the half-bridge circuit includes a high-side power device and a low-side power device in a power module, and the first power device is one of the high-side power device and the low-side power device.

8. The system of claim 6, wherein the gate driver comprises:
a hold circuit configured to hold a peak value of the voltage across the source wire; and
an analog-to-digital converter (ADC) configured to convert the peak value of the voltage across the source wire into a digital signal, wherein output of the voltage across the source wire to the controller comprises outputting the digital signal to the controller.

9. The system of claim 8, further comprising a sensing wire connected to the hold circuit, wherein the voltage across the source wire is measured by the gate driver based on mutual inductance between the sensing wire and the source wire.

10. The system of claim 6, wherein the gate driver comprises:
a comparator configured to:
determine the voltage across the source wire is greater than a predefined threshold; and
in response to the determination that the voltage across the source wire is greater than the predefined threshold, output a signal to the controller that indicates the voltage across the source wire is greater than the predefined threshold.

11. The system of claim 6, further comprising an ADC configured to:
detect a direct current (DC) link voltage of a main power loop supplied to the half-bridge circuit; and
sending the DC link voltage to the controller, wherein the controller is configured to determine a peak drain-source voltage of the first power device based on at least the overshoot voltage and the DC link voltage.

12. The system of claim 6, wherein the half-bridge circuit includes a high-side power device and a low-side power device in a power module, and the controller is configured to determine the overshoot voltage based on voltages across source wires of both the high-side power device and the low-side power device.

13. The system of claim 6, wherein:
the half-bridge circuit includes a main power loop formed by at least one wire having stray inductances and a pair of power devices including a high-side power device and a low-side power device in a power module;
the first power device is one of the pair of power devices;
the at least one wire includes the source wire of the first power device and a source wire of a second power device among the pair of power devices;
the controller is configured to:
determine the overshoot voltage based on the stray inductances of the at least one wire in the main power loop and a maximum of the voltage across the source wire of the first power device; and
determine the peak drain-source voltage of the first power device based on the overshoot voltage, a drain-source voltage of the second power device, and a DC link voltage of the main power loop.

14. The system of claim 13, wherein the controller is configured to, during a transition of the first power device from an ON state to an OFF state:
set the drain-source voltage of the second power device to zero; and
determine the peak drain-source voltage of the first power device based on the overshoot voltage and the DC link voltage of the main power loop.

15. A method comprising:
measuring a voltage across a source wire of a power device;
determining, based on at least the voltage across the source wire, an overshoot voltage associated with the power device;
determining, based on at least the overshoot voltage, a peak drain-source voltage of the power device; and
adjusting, based on the determined peak drain-source voltage, a control signal for driving the power device.

16. The method of claim 15, wherein the power device is one of a high-side power device and a low-side power device in a power module.

17. The method of claim 15, wherein measuring the voltage across the source wire comprises operating a peak hold circuit to hold a peak value of the voltage across the source wire.

18. The method of claim 15, wherein measuring the voltage across the source wire comprises measuring a mutual inductance between a sensing wire and the source wire.

19. The method of claim 15, wherein:
the power device is a first power device among a pair of power devices including a high-side power device and a low-side power device in a power module;
the pair of power devices and at least one wire having stray inductances form a main power loop;
the at least one wire includes the source wire of the first power device and a source wire of a second power device among the pair of power devices;
the method further comprising:
determining the overshoot voltage based on stray inductances of the at least one wire in the main power loop and a maximum of the voltage across the source wire of the first power device; and
determining the peak drain-source voltage of the power device based on the overshoot voltage, a drain-source voltage of the second power device, and a DC link voltage of the main power loop.

20. The method of claim 19, further comprising:
during a transition of the power device from an ON state to an OFF state, setting the drain-source voltage of a second power device among the pair of power devices to zero; and
determining the peak drain-source voltage of the power device based on the overshoot voltage and the DC link voltage of the main power loop.
